(19) United States
(12) Patent Application Publication
(10) Pub. No.: US 2025/0224141 A1
(43) Pub. Date: Jul. 10, 2025

(54) THERMOELECTRIC VORTEX TUBES

(71) Applicant: Hamilton Sundstrand Corporation, Charlotte, NC (US)

(72) Inventors: Debabrata Pal, Hoffman Estates, IL (US); Viktor Kilchyk, Lancaster, NY (US)

(73) Assignee: Hamilton Sundstrand Corporation, Charlotte, NC (US)

(21) Appl. No.: 18/407,762

(22) Filed: Jan. 9, 2024

(51) Int. Cl. F24H 3/08; B33Y 10/00; B33Y 80/00; F24F 5/00; F24H 9/1863; H10N 10/01; H10N 10/10; H10N 10/817

(52) U.S. Cl. CPC F24H 3/081; F24F 5/0042; F24H 9/1863; H10N 10/01; H10N 10/10; H10N 10/817; B33Y 10/00; B33Y 80/00; F24H 2240/08; F24H 2250/06

(57) ABSTRACT

A system includes a vortex tube. A first thermoelectric terminal is in thermal communication with the first outlet of the vortex tube. A second thermoelectric terminal is in thermal communication with the second outlet of the vortex tube. An electrical circuit is electrically connected to the first thermoelectric terminal and to the second thermoelectric terminal for electrical conduction of Peltier-effect thermoelectric current. The systems and methods described herein can be used to enhance temperature difference generated in a vortex tube, and/or to harvest energy from the temperature difference in a vortex tube.

### BACKGROUND

### 1. Field

The present disclosure relates to vortex tubes, and more particularly to thermoelectric aspects of vortex tubes.

### 2. Description of Related Art

Vortex tubes are used to convert potential energy of a compressed gas into two streams, one of hot gas and another of cold gas. The cooled gas can be used for thermal management, e.g. of electronic or mechanical systems. The heated gas can be used for heating if applicable. Vortex tubes are advantageous means for cooling and/or heating. One reason is few or no moving parts. There can be a considerable temperature difference, e.g. up to 160° K, and relatively low pressure ratios can drive the temperature difference, e.g. pressure ratios as low as 1.3.

The conventional techniques have been considered satisfactory for their intended purpose. However, there is an ever present need for improved systems and methods for utilization of vortex tubes. This disclosure provides a solution for this need.

### SUMMARY

A system includes a vortex tube. The vortex tube includes an inlet configured to receive compressed gas from a compressed gas source, a spin chamber in fluid communication with the inlet configured to receive a flow of compressed gas from the inlet and to impart spin on the flow of gas, a first outlet in fluid communication with the spin chamber, configured to discharge a cooled portion of the flow of gas, and a second outlet in fluid communication with the spin chamber, configured to discharge a heated portion of the flow of gas. A first thermoelectric terminal is in thermal communication with the first outlet. A second thermoelectric terminal is in thermal communication with the second outlet. An electrical circuit is electrically connected to the first thermoelectric terminal and to the second thermoelectric terminal for electrical conduction of Peltier-effect thermoelectric current.

An expansion nozzle can be defined between the spin chamber and the first outlet for cooling expanded gas. The second outlet can be configured to exhaust reciprocal heated gas from the vortex tube.

The electrical circuit can be configured to harvest energy from the heat flux at the first and second thermoelectric terminals. The electrical circuit can be electrically connected to an electric power consuming system. The electrical circuit can be electrically connected to an electrical energy storage.

The electrical circuit can be configured to supply power to drive heat flux at the first and second thermoelectric terminals. The electrical system can be electrically connected to a source of electrical power.

The first thermoelectrical terminal can be in thermal communication with a cold air passage in fluid communication downstream of the first outlet. The second thermoelectric terminal can be in thermal communication with a hot air passage in fluid communication downstream of the second outlet. The first thermoelectric terminal can include a first side of an n-type semiconductor electrically connected to a first leg of the electrical circuit and a first side of a p-type semiconductor electrically connected to a second leg of the electrical circuit. The second thermoelectrical junction can include a series connector connecting a second end of the n-type semiconductor in series with a second end of the p-type semiconductor.

The first thermoelectric terminal can include a first thermoelectric junction of dissimilar metals, and the second thermoelectric terminal can include a second thermoelectric junction of dissimilar metals. The first thermoelectric junction of dissimilar metals can include a first metallic material of the first outlet joined to a second metallic material of the vortex tube. The second thermoelectric junction of dissimilar metals can include a third metallic material of the second outlet jointed to the second metallic material of the vortex tube. The first metallic material and the second metallic material can be joined together at an additively manufactured interface, including a single crystal structure boundary devoid of a heat effected zone. The third metallic material and the second metallic material can be joined together at an additively manufactured interface, including a single crystal structure boundary devoid of a heat effected zone. The first, second, and third metallic materials can be a single monolithic structure.

A method includes driving electrical current through an electrical circuit that is electrically connected to a first thermoelectric terminal and to a second thermoelectric terminal as described above. This can include harvesting energy from the vortex tube. It is also contemplated that driving electrical current can include using electrical power from a power supply to drive heat flux at the first and second thermoelectric terminals to cool down cool gas flow of the first outlet and to heat up hot gas flow of the second outlet and/or to heat up gas flow of the first outlet and cool down gas flow of the second outlet.

A method includes additively manufacturing a vortex tube including an expansion nozzle. Additively manufacturing can include forming a first thermoelectric junction of a first metallic material and a second metallic material in thermal communication with the expansion nozzle. Additively manufacturing can include forming a second thermoelectric junction of a third metallic material and the second metallic material in thermal communication with a heated gas outlet of the vortex tube.

These and other features of the systems and methods of the subject disclosure will become more readily apparent to those skilled in the art from the following detailed description of the preferred embodiments taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, preferred embodiments thereof will be described in detail herein below with reference to certain figures, wherein:

FIG. 1 is a schematic cross-sectional side-elevation view of an embodiment of a system constructed in accordance with the present disclosure, showing two thermoelectric junctions incorporated in a vortex tube; and

FIG. 2 is a schematic view of another embodiment of the system of FIG. 1, showing thermoelectric terminals in thermal communication with the heated and cooled gases from the vortex tube.

### DETAILED DESCRIPTION OF THE PREFERRED EMBODIMENTS

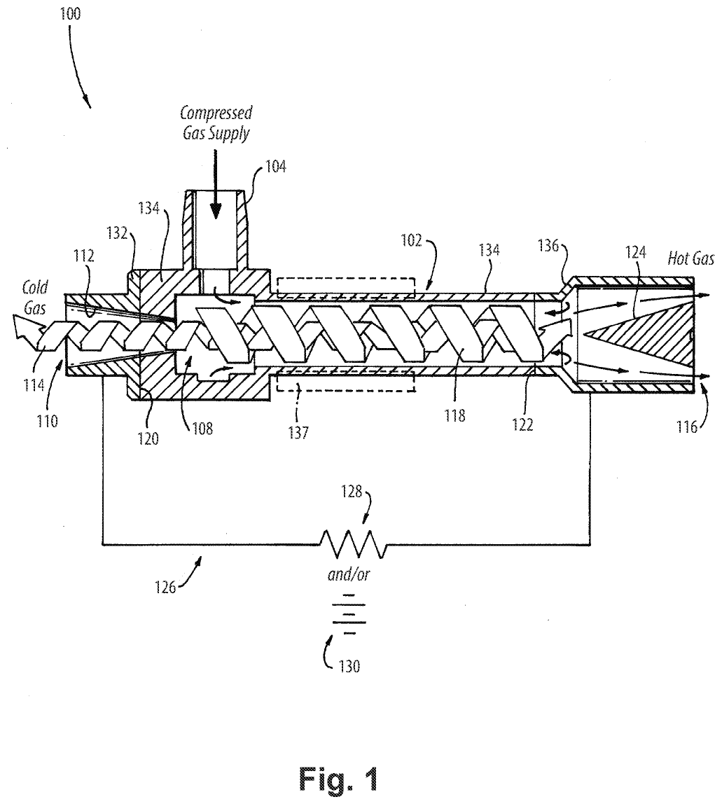

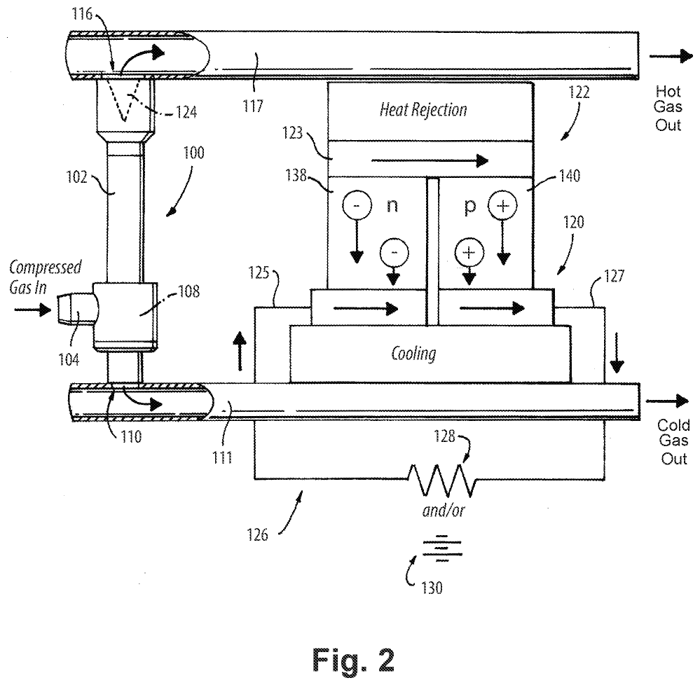

Reference will now be made to the drawings wherein like reference numerals identify similar structural features or aspects of the subject disclosure. For purposes of explanation and illustration, and not limitation, a partial view of an embodiment of a system in accordance with the disclosure is shown in FIG. 1 and is designated generally by reference character 100. Other embodiments of systems in accordance with the disclosure, or aspects thereof, are provided in FIG. 2, as will be described. The systems and methods described herein can be used to enhance temperature difference generated in a vortex tube, and/or to harvest energy from the temperature difference in a vortex tube.

The system 100 includes a vortex tube 102. The vortex tube 102 has an inlet 104 configured to receive compressed gas from a compressed gas source 106, e.g. compressed air. A spin chamber 108 is in fluid communication with the inlet 104 and is configured to receive a flow of compressed gas from the inlet 104 and to impart spin on the flow of gas. A first outlet 110 is in fluid communication with the spin chamber 108, and is configured to discharge a cooled portion of the flow of gas from the spin chamber. An expansion nozzle 112 is defined between the spin chamber 108 and the first outlet 110 for cooling the expanded gas 114, e.g. as in an isenthalpic nozzle or throttle such as used in refrigeration cycles. A second outlet 116 is in fluid communication with an opposite side of the spin chamber 108 from the first outlet 110. The second outlet 110 is configured to discharge a heated portion 118 of the flow of gas. The second outlet 110 is configured to exhaust reciprocal heated gas from the vortex tube, i.e. through a generally cylindrical passage from the spin chamber 108 to the outlet 116 without an expansion nozzle. An optional control valve 124 can be included in the outlet 116.

A first thermoelectric terminal 120 is in thermal communication with the first outlet 110, e.g. through thermal conduction and/or convection. A second thermoelectric terminal 122 is in thermal communication with the second outlet 116, e.g. through thermal conduction and/or convection. An electrical circuit 126 is electrically connected to the first thermoelectric terminal 120 and to the second thermoelectric terminal 122 for electrical conduction of Peltier-effect thermoelectric current.

In an energy harvesting mode, the electrical circuit 126 can be used to harvest energy from the heat flux at the first and second thermoelectric terminals 120, 122 to power a load 128, e.g. any electric power consuming system, and/or can supply energy to an electrical energy storage 130 such as a battery, capacitor, supercapacitor, or the like. In an energy consuming mode, the electrical circuit 126, is configured to supply power from a source of electrical power, e.g. storage 130, a generator, or the like, to drive heat flux at the first and second thermoelectric terminals 120, 120, e.g. to enhance or control gas temperatures of the outlets 110 and/or 116. This can heat the gas flow at the cold outlet 110 and cool gas flow at the hot outlet 116, or can add to the cooling effect at the cold outlet 110 and add heat to the gas flow at the hot outlet 116, depending on which direction the current is driven in the circuit 126.

The first thermoelectric terminal 120 can include a first thermoelectric junction of dissimilar metals 132, 134, and the second thermoelectric terminal 122 can include a second thermoelectric junction of dissimilar metals 134, 136. The first thermoelectric junction of dissimilar metals includes a first metallic material 132 of the first outlet 110 joined to a second metallic material 134 of the vortex tube 102. The second thermoelectric junction of dissimilar metals includes a third metallic material 136 of the second outlet 116 jointed to the second metallic material 134 of the vortex tube 102. The first metallic material 132 and the second metallic material 134 are joined together at an additively manufactured interface (the terminal 120), including a single crystal structure boundary, i.e. no braze or solder are in the interface, and the interface is devoid of a heat effected zone such as would result from welding. The third metallic material 136 and the second metallic material 134 are joined together at an additively manufactured interface, i.e. the terminal 122, including a similar single crystal structure boundary from additive manufacturing as that described above for terminal 120. The first, second, and third metallic materials 132, 134, 136 are a single monolithic additively manufactured structure, although those skilled in the art will readily appreciate that conventional manufacturing techniques can be used to form this structure as well. It is also contemplated that a buffer element 137 can be included in the vortex tube 102, separating the hot and cold gas regions. This can reduce or eliminate parasitic heat transfer within the vortex tube 102 itself. The layer of buffer element 137 can be made with a metal additively manufactured foam, lattice, voided structure, or the like, to work as thermal insulation. It could also be made from a polymer as an insert.

With reference now to FIG. 2, the system 100 is shown with a different thermoelectric terminal configuration. The first thermoelectrical terminal 120 is in thermal communication with a cold air passage 111 in fluid communication downstream of the first outlet 110. The second thermoelectric terminal 122 is in thermal communication with a hot air passage 117 in fluid communication downstream of the second outlet 116. The first thermoelectric terminal 120 includes a first side of an n-type semiconductor 138 electrically connected to a first leg 125 of the electrical circuit 126 and a first side of a p-type 140 semiconductor electrically connected to a second leg 127 of the electrical circuit 126. The first sides of the n-type and p-type semiconductors 138, 140 are not directly connected together, i.e. they are isolated from one another. The first and second legs 125, 127 of the circuit 126 are on opposite sides of the load/storage 128/130. The second thermoelectrical junction 122 includes a series connector 123 connecting a second end of the n-type semiconductor 138 in series with a second end of the p-type semiconductor 140. The configuration in FIG. 2 can run in the energy harvesting or energy consuming modes described above with respect to FIG. 1. Those skilled in the art will readily appreciate that dissimilar metal junctions can be used in the configuration in FIG. 2 in addition to or in lieu of the semiconductor based terminals, or any other suitable Peltier-Seebeck elements.

The method includes driving electrical current through an electrical circuit that is electrically connected to a first thermoelectric terminal 120 and to a second thermoelectric terminal 122 as described above. Driving electrical current can include harvesting energy from the vortex tube 102. It is also contemplated that driving electrical current can include using electrical power from a power supply 130 to drive heat flux at the first and second thermoelectric terminals 120, 122 to cool down cool gas flow of the first outlet 110 and/or to heat up hot gas flow of the second outlet 116.

Systems and methods as disclosed herein provide potential benefits including the following. They can provide higher cooling capacity per unit weight as compared to either (thermoelectric generator) TEG or (vortex tube) VT standalone devices. They can also operate with no moving parts, and with relative simplicity, small size and low costs, high reliability, and increasing cooling output with no or minimal weight change relative to traditional systems. Systems and methods as disclosed herein can be applicable to a hot spot/electronic cooling or any suitable application.

The methods and systems of the present disclosure, as described above and shown in the drawings, provide for enhancing temperature difference generated in a vortex tube by supplying electrical power, and/or to harvest energy from the temperature difference in a vortex tube. While the apparatus and methods of the subject disclosure have been shown and described with reference to preferred embodiments, those skilled in the art will readily appreciate that changes and/or modifications may be made thereto without departing from the scope of the subject disclosure.

What is claimed is:

1. A system comprising:
a vortex tube including:
an inlet configured to receive compressed gas from a compressed gas source;
a spin chamber in fluid communication with the inlet configured to receive a flow of compressed gas from the inlet and to impart spin on the flow of gas;
a first outlet in fluid communication with the spin chamber, configured to discharge a cooled portion of the flow of gas; and
a second outlet in fluid communication with the spin chamber, configured to discharge a heated portion of the flow of gas;
a first thermoelectric terminal in thermal communication with the first outlet;
a second thermoelectric terminal in thermal communication with the second outlet; and
an electrical circuit electrically connected to the first thermoelectric terminal and to the second thermoelectric terminal for electrical conduction of Peltier-effect thermoelectric current.

2. The system as recited in claim 1, wherein the electrical circuit is configured to harvest energy from heat flux at the first and second thermoelectric terminals.

3. The system as recited in claim 2, wherein the electrical circuit is electrically connected to an electric power consuming system.

4. The system as recited in claim 2, wherein the electrical circuit is electrically connected to an electrical energy storage.

5. The system as recited in claim 1, wherein the electrical circuit is configured to supply power to drive heat flux at the first and second thermoelectric terminals.

6. The system as recited in claim 5, wherein the electrical system is electrically connected to a source of electrical power.

7. The system as recited in claim 5, wherein the first thermoelectrical terminal is in thermal communication with a cold air passage in fluid communication downstream of the first outlet, and wherein the second thermoelectric terminal is in thermal communication with a hot air passage in fluid communication downstream of the second outlet.

8. The system as recited in claim 7, wherein the first thermoelectric terminal includes a first side of an n-type semiconductor electrically connected to a first leg of the electrical circuit and a first side of a p-type semiconductor electrically connected to a second leg of the electrical circuit, wherein the second thermoelectrical junction includes a series connector connecting a second end of the n-type semiconductor in series with a second end of the p-type semiconductor.

9. The system as recited in claim 1, wherein the first thermoelectric terminal includes a first thermoelectric junction of dissimilar metals, wherein the second thermoelectric terminal includes a second thermoelectric junction of dissimilar metals.

10. The system as recited in claim 9, wherein the first thermoelectric junction of dissimilar metals includes a first metallic material of the first outlet joined to a second metallic material of the vortex tube.

11. The system as recited in claim 10, wherein the second thermoelectric junction of dissimilar metals includes a third metallic material of the second outlet jointed to the second metallic material of the vortex tube.

12. The system as recited in claim 11, wherein the first metallic material and the second metallic material are joined together at an additively manufactured interface, including a single crystal structure boundary devoid of a heat effected zone.

13. The system as recited in claim 12, wherein the third metallic material and the second metallic material are joined together at an additively manufactured interface, including a single crystal structure boundary devoid of a heat effected zone.

14. The system as recited in claim 13, wherein the first, second, and third metallic materials are a single monolithic structure.

15. The system as recited in claim 1, wherein an expansion nozzle is defined between the spin chamber and the first outlet for cooling expanded gas, and wherein the second outlet is configured to exhaust reciprocal heated gas from the vortex tube.

16. A method comprising:
driving electrical current through an electrical circuit that is electrically connected to a first thermoelectric terminal and to a second thermoelectric terminal, wherein the first thermoelectric terminal is in thermal communication with the first outlet of a vortex tube, wherein the second thermoelectric terminal is in thermal communication with the second inlet of the vortex tube.

17. The method as recited in claim 16, wherein driving electrical current includes harvesting energy from the vortex tube.

18. The method as recited in claim 17, wherein driving electrical current includes using electrical power from a power supply to drive heat flux at the first and second thermoelectric terminals to cool down cool gas flow of the first outlet and/or to heat up hot gas flow of the second outlet.

19. A method comprising:
additively manufacturing a vortex tube including an expansion nozzle wherein additively manufacturing includes forming a first thermoelectric junction of a first metallic material and a second metallic material in thermal communication with the expansion nozzle.

20. The method as recited in claim 19, wherein additively manufacturing includes forming a second thermoelectric junction of a third metallic material and the second metallic material in thermal communication with a heated gas outlet of the vortex tube.
